(19) United States
(12) Patent Application Publication
(10) Pub. No.: US 2026/0318948 A1
(43) Pub. Date: Oct. 15, 2026

(54) TEST APPARATUS FOR REDUCING A CONTACT AREA BETWEEN A TEST SOCKET AND A SEMICONDUCTOR PACKAGE

(71) Applicant: Samsung Electronics Co., Ltd., Suwon-si (KR)

(72) Inventors: Hyun YANG, Suwon-si (KR); Young Woo KIM, Suwon-si (KR)

(73) Assignee: Samsung Electronics Co., Ltd., Suwon-si (KR)

(21) Appl. No.: 19/467,002

(22) Filed: Feb. 2, 2026

(30) Foreign Application Priority Data
Feb. 3, 2025 (KR) 10-2025-0013312

(51) Int. Cl. G01R 1/04

(52) U.S. Cl. CPC G01R 1/0408

(57) ABSTRACT

A test socket includes a base plate defining first through-holes, and a floating plate over the base plate and defining second through-holes vertically overlapping the respective first through-holes. The floating plate includes a thin portion and a thick portion having a thickness greater than a thickness of the thin portion. The test socket further includes socket pins in the first through-holes and the second through-holes. The first through-holes and the second through-holes vertically overlap each other with the socket pins therein.

### CROSS-REFERENCE TO RELATED APPLICATIONS

This U.S. non-provisional application claims priority under 35 U.S.C. § 119 to Korean Patent Application No. 10-2025-0013312 filed on Feb. 3, 2025, in the Korean Intellectual Property Office, the entire disclosure of which is incorporated herein by reference.

### BACKGROUND

Some example embodiments of the present disclosure relate to a test apparatus.

A semiconductor package manufactured through a semiconductor manufacturing process is subject to various test processes to verify the reliability of the product. Through the test processes, the semiconductor package may be determined as a normal product or a defective product. Accordingly, a reliable semiconductor package product may be obtained. A general test process may include an electrical characteristic test to examine electrical characteristics and defects of a semiconductor package, and the state of the semiconductor package may be checked by bringing external terminals of the semiconductor package into contact with a test board equipped with a test signal generation circuit.

### SUMMARY

Some example embodiments of the present disclosure provide a test apparatus for reducing a contact area between a test socket and a semiconductor package.

According to some example embodiments, a test socket includes a base plate defining first through-holes, a floating plate over the base plate and that defines second through-holes vertically overlapping the respective first through-holes, and includes a thin portion and a thick portion having a thickness greater than a thickness of the thin portion, and socket pins in the first through-holes and the second through-holes, the first through-holes and the second through-holes vertically overlapping with each other.

According to some example embodiments, a test socket includes a base plate defining first through-holes, a floating plate over the base plate and having a trench recessed from a portion of an upper surface of the floating plate, the floating plate including a thick portion on a first side of the trench and a thin portion in the trench and defining second through-holes configured to penetrate the thin portion and the thick portion, and the second through-holes vertically overlap the respective first through-holes, and socket pins in the first through-holes and the second through-holes, the first through-holes and the second through-holes vertically overlapping with each other.

According to some example embodiments, a test apparatus includes a test board, a base plate on the test board and defining first through-holes, a floating plate over the base plate and defining second through-holes vertically overlapping the respective first through-holes, and includes a thin portion and a thick portion having a thickness greater than a thickness of the thin portion, and socket pins in the first through-holes and the second through-holes, the first through-holes and the second through-holes vertically overlapping with each other. The test board is configured to electrically connect to the socket pins and configured to transmit and receive test signals.

### BRIEF DESCRIPTION OF THE FIGURES

The above and other objects and features of the present disclosure will become apparent by describing in detail embodiments thereof with reference to the accompanying drawings.

FIG. 1 is a plan view of a test apparatus according to some example embodiments of the present disclosure.

FIG. 2 is a cross-sectional view taken along line I-I′ of FIG. 1.

FIG. 3 is a cross-sectional view taken along line II-II′ of FIG. 1.

FIG. 4 is a plan view of a test apparatus according to some example embodiments of the present disclosure.

FIG. 5 is a cross-sectional view taken along line I-I′ of FIG. 4.

FIGS. 6, 7, and 8 are cross-sectional views illustrating a test apparatus operating method according to some example embodiments of the present disclosure.

FIGS. 9 and 10 are cross-sectional views illustrating the test apparatuses according to some example embodiments of the present disclosure.

FIGS. 11 and 12 are flowcharts illustrating a test apparatus operating method according to some example embodiments of the present disclosure.

FIGS. 13, 14, 15, and 16 are plan views of test apparatuses according to some example embodiments of the present disclosure.

FIG. 17 is a plan view illustrating a test apparatus according to some example embodiments of the present disclosure.

FIG. 18 is a cross-sectional view taken along line I-I′ of FIG. 17.

### DETAILED DESCRIPTION OF EXAMPLE EMBODIMENTS

Hereinafter, example embodiments of the present disclosure will be described in detail with reference to the accompanying drawings.

When the terms “about” or “substantially” are used in this specification in connection with a numerical value, it is intended that the associated numerical value includes a manufacturing or operational tolerance (e.g., ±10%) around the stated numerical value. Moreover, when the words “about” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

As used herein, the term “and/or” includes any and all combinations of one or more of the associated listed items. Expressions such as “at least one of,” when preceding a list of elements, modify the entire list of elements and do not modify the individual elements of the list. For example, “at least one of A, B, and C,” and similar language (e.g., “at least one selected from the group consisting of A, B, and C,” “at least one of A, B, or C”) may be construed as A only, B only, C only, or any combination of two or more of A, B, and C, such as, for instance, ABC, AB, BC, and AC.

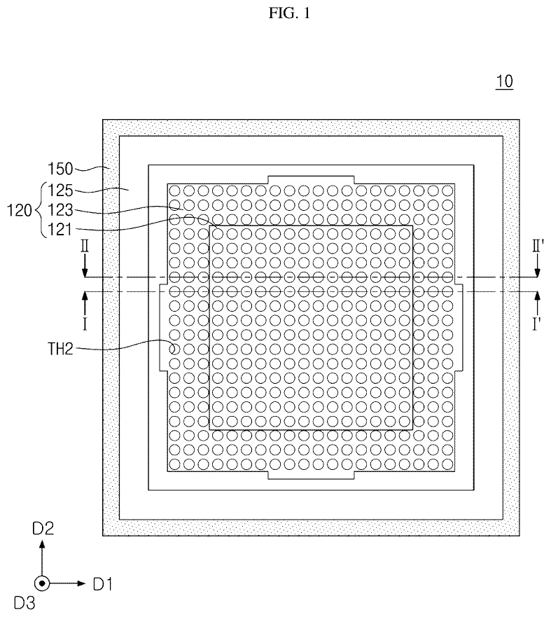

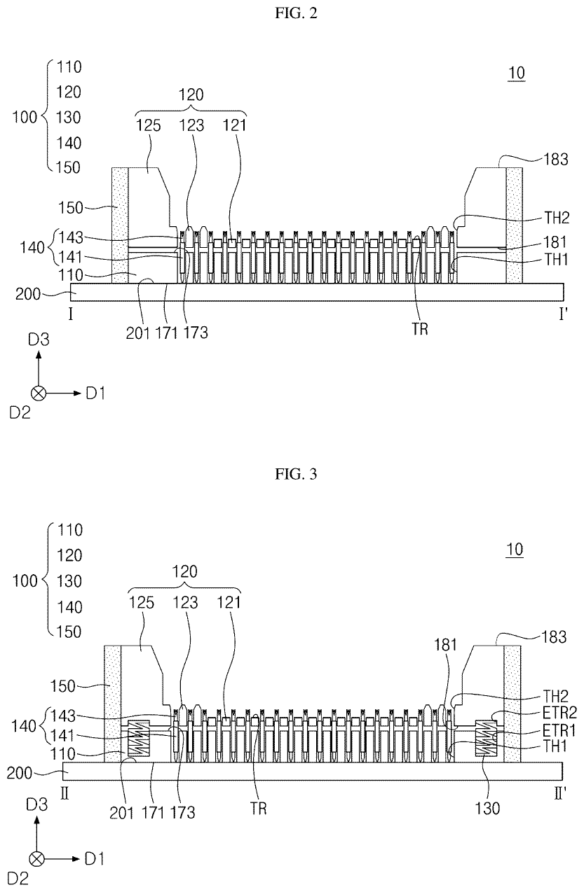

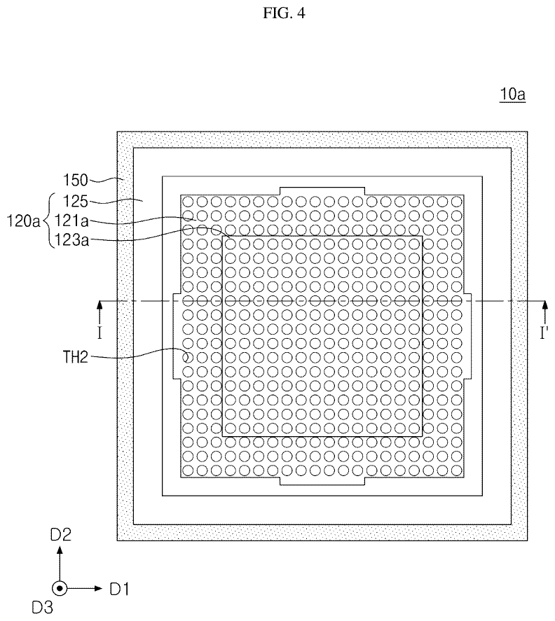

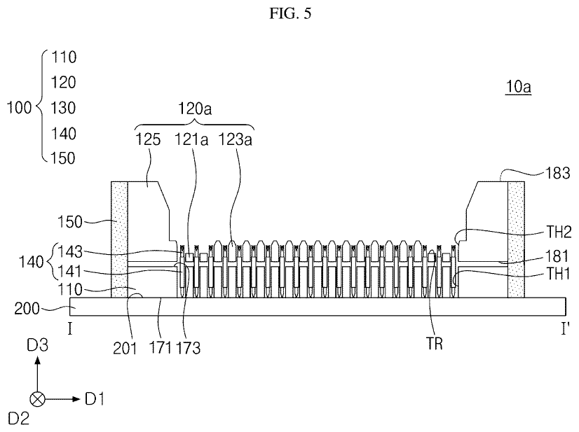

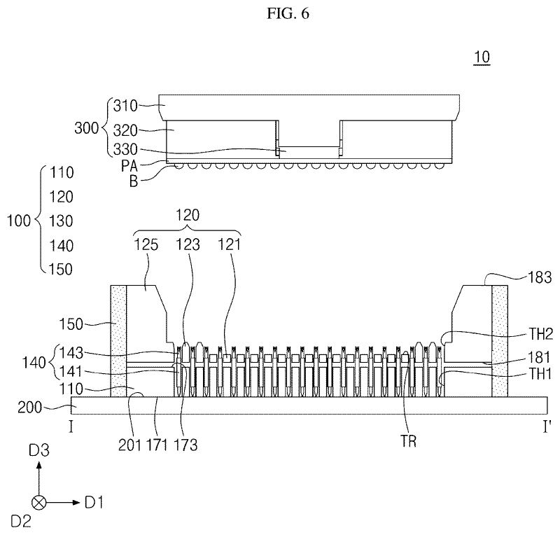

FIG. 1 is a plan view of a test apparatus 10 according to some example embodiments of the present disclosure. FIG. 2 is a cross-sectional view taken along line I-I′ of FIG. 1. FIG. 3 is a cross-sectional view taken along line II-II′ of FIG. 1. FIG. 4 is a plan view of a test apparatus 10a, according to some example embodiments of the present disclosure. FIG. 5 is a cross-sectional view taken along line I-I′ of FIG. 4. FIGS. 6 to 8 are cross-sectional views illustrating a test apparatus operating method according to some example embodiments of the present disclosure.

Referring to FIGS. 1 to 3, the test apparatus 10, according to some example embodiments, may include a test socket 100 and a test board 200. The test socket 100 may include a base plate 110, a floating plate 120, an elastic member 130, socket pins 140, and a cover 150.

The base plate 110 may be provided on the test board 200. The base plate 110 may have a lower surface 171 that contacts the upper surface 201 of the test board 200 and an upper surface 173 that is opposite the lower surface 171 of the base plate 110. Furthermore, the base plate 110 may have a plurality of first through-holes TH1. The first through-holes TH1 may penetrate the base plate 110. In some example embodiments, the first through-holes TH1 may penetrate the upper surface 173 and the lower surface 171 of the base plate 110 and the body of the base plate 110 between the upper surface 173 and the lower surface 171 of the base plate 110. In some example embodiments, the socket pins 140 may be inserted into the first through-holes TH1, respectively. In addition, the base plate 110 may have a first elastic-member trench ETR1. The first elastic-member trench ETR1 may be a trench recessed from a portion of the upper surface 173 of the base plate 110. The base plate 110 may be formed of or include at least one of engineering plastics. For example, the base plate 110 may be formed of or include at least one of a polyamide-based material, a polyacetal-based material, a polycarbonate-based material, a polybutylene terephthalate-based material, a modified polyphenylene oxide-based material, a polyimide-based material, a polysulfone-based material, a polyphenylene sulfide-based material, a polyamide-imide-based material, or a polyetheretherketone-based material, but is not limited thereto. The base plate 110 may be formed of or include MDS100, vespel, tolron, polyetheretherketone (PEEK), or ceramic. In addition, the base plate 110 may be formed of or include at least one material having a surface resistance of 10¹³ ohms (or about 10¹³ ohms) or more.

The floating plate 120 may be provided or arranged over the base plate 110. The floating plate 120 may have a lower surface 181 that faces toward the upper surface 173 of the base plate 110 and an upper surface 183 that is opposite the lower surface 181 of the floating plate 120. In addition, the floating plate 120 may include a thin (or first) portion 121, a thick (or second) portion 123, and an edge portion 125, and may have or otherwise define a trench TR recessed from a portion (e.g., from a central portion) of the upper surface 183 of the floating plate 120. The inner surfaces of the trench TR may be perpendicular (or substantially perpendicular) to the lower surface 181 of the floating plate 120. However, in some example embodiments, the inner surfaces of the trench TR (or portions thereof) may be inclined toward (or with respect to) the lower surface 181 of the floating plate 120. In some example embodiments, the distance between the inner surfaces (or sidewalls) of the trench TR may be decreased from the upper surface 183 to the lower surface 181 of the floating plate 120. The floating plate 120 may be formed of or include at least one of engineering plastics. For example, the floating plate 120 may be formed of or include at least one of a polyamide-based material, a polyacetal-based material, a polycarbonate-based material, a polybutylene terephthalate-based material, a modified polyphenylene oxide-based material, a polyimide-based material, a polysulfone-based material, a polyphenylene sulfide-based material, a polyamide-imide-based material, or a polyetheretherketone-based material, but is not limited thereto. The floating plate 120 may be formed of or include MDS100, vespel, tolron, polyetheretherketone (PEEK), or ceramic. In addition, the floating plate 120 may be formed of or include at least one material having a surface resistance of 10¹³ ohms (or about 10¹³ ohms) or more.

The thin portion 121 may be a body of the floating plate 120 in the trench TR. The thin portion 121 may be a portion of the floating plate 120 that is thinner than the thick portion 123. In some example embodiments, in the direction D3 in FIGS. 2-3, the thin portion 121 may have a thickness smaller than the thickness of the thick portion 123.

The thick portion 123 may be a body of the floating plate 120 on one side (or outer side) of the trench TR. The thick portion 123 may be a portion of the floating plate 120 that is thicker than the thin portion 121. In some example embodiments, in the direction D3 in FIGS. 2-3, the thick portion 123 may have a thickness greater than the thickness of the thin portion 121.

In some example embodiments, the difference between the thickness of the thin portion 121 and the thickness of the thick portion 123 may range from 0.05 mm (or about 0.05 mm) to 5 mm (or about 5 mm). For example, the difference between the thickness of the thin portion 121 and the thickness of the thick portion 123 may range from 0.05 mm (or about 0.05 mm) to 2 mm (or about 2 mm). For example, the difference between the thickness of the thin portion 121 and the thickness of the thick portion 123 may range from 0.1 mm (or about 0.1 mm) to 0.5 mm (or about 0.5 mm).

In some example embodiments, the lower surface of the thin portion 121 may be coplanar with the lower surface of the thick portion 123. The lower surface of the thin portion 121 and the lower surface of the thick portion 123 may generally define at least a portion of the lower surface 181 of the floating plate 120. Since the thin portion 121 is thinner than the thick portion 123 as described above, the upper end (or surface) of the thin portion 121 may be lower than the upper end (or surface) of the thick portion 123.

In some example embodiments, the planar area of the thin portion 121 may range from 50% (or about 50%) to 90% (or about 90%) of the sum of the planar areas of the thin portion 121 and the thick portion 123. For example, the planar area of the thin portion 121 may range from 50% (or about 50%) to 80% (or about 80%) of the sum of the planar areas of the thin portion 121 and the thick portion 123. For example, the planar area of the thin portion 121 may range from 55% (or about 55%) to 75% (or about 75%) of the sum of the planar areas of the thin portion 121 and the thick portion 123.

The floating plate 120 may have a plurality of second through-holes TH2. The second through-holes TH2 may penetrate the floating plate 120. In some example embodiments, the second through-holes TH2 may penetrate the upper surface 183 and the lower surface 181 of the floating plate 120 and the body of the floating plate 120 between the upper surface 183 and the lower surface 181 of the floating plate 120. In some example embodiments, the thin portion 121 and the thick portion 123 may have or otherwise define the plurality of second through-holes TH2. In some example embodiments, the second through-holes TH2 may penetrate the upper and lower surfaces of the thin portion 121, the body of the thin portion 121 between the upper and lower surfaces of the thin portion 121, the upper and lower surfaces of the thick portion 123, and the body of the thick portion 123 between the upper and lower surfaces of the thick portion 123. In some example embodiments, the socket pins 140 may be inserted into the second through-holes TH2. In some example embodiments, a socket pin 140 may be inserted into each second through-hole TH2. In some example embodiments, the second through-holes TH2 may vertically overlap respective first through-holes TH1. In some example embodiments, the second through-holes TH2 may vertically align with respective first through-holes TH1. In some example embodiments, each socket pin 140 may be received in a corresponding second through-hole TH2 and first through-hole TH1.

The edge portion 125 may surround the thin portion 121 and the thick portion 123 when viewed in a plan view. In some example embodiments, the edge portion 125 may be provided along the periphery of the thin portion 121 and/or the thick portion 123 while contacting portions of the thin portion 121 and/or the thick portion 123. In some example embodiments, the level of the upper surface of the edge portion 125 may be higher than the level of the upper end (or surface) of the thick portion 123. In addition, a portion of the edge portion 125 may have an inclined surface.

The lower surface of the edge portion 125 may be coplanar with the lower surface of the thin portion 121 and/or the lower surface of the thick portion 123. The lower surface of the edge portion 125, the lower surface of the thin portion 121, and the lower surface of the thick portion 123 may generally define at least a portion of the lower surface 181 of the floating plate 120. Since the level of the upper surface of the edge portion 125 is higher than the level of the upper end (or surface) of the thick portion 123 as described above, the edge portion 125 may have a thickness greater than the thickness of the thin portion 121 and/or the thickness of the thick portion 123.

The thin portion 121, the thick portion 123, and the edge portion 125 may be formed of or include different materials. Alternatively, one or more of the thin portion 121, the thick portion 123, and the edge portion 125 may be formed of or include the same material or similar materials. In some example embodiments, the thin portion 121, the thick portion 123, and the edge portion 125 may be formed of or include the same material. When the thin portion 121, the thick portion 123, and the edge portion 125 are formed of or include the same material, the thin portion 121, the thick portion 123, and the edge portion 125 may be integrally formed with one another, and may, for example, form a single, unitary structure.

The floating plate 120 may have or define a second elastic-member trench ETR2. The second elastic-member trench ETR2 may be a trench recessed from a portion of the lower surface 181 of the floating plate 120. In some example embodiments, the edge portion 125 of the floating plate 120 may have or define the second elastic-member trench ETR2. The second elastic-member trench ETR2 may be a trench recessed from a portion of the lower surface of the edge portion 125.

The elastic member 130 may be provided or arranged between the base plate 110 and the floating plate 120. In some example embodiments, the lower surface of the elastic member 130 may contact the upper surface 173 of the base plate 110, and the upper surface of the elastic member 130 may be brought into contact with the lower surface 181 of the floating plate 120. Accordingly, the elastic member 130 may space (or separate) the base plate 110 and the floating plate 120 apart from each other and may be configured to contract or expand to adjust the position level of the floating plate 120. In some example embodiments, the elastic member 130 may be a spring, for example, a coil spring. The elastic member 130 is not limited to a spring, and may be any device of a desired material, type, size, and shape that has or provides an elastic force capable of spacing (or separating) the base plate 110 and the floating plate 120 apart from each other.

In some example embodiments, the elastic member 130 may be provided or arranged in the first elastic-member trench ETR1 and/or the second elastic-member trench ETR2. For example, the elastic member 130 may be provided or arranged in the first elastic-member trench ETR1. For example, the elastic member 130 may be provided or arranged in the second elastic-member trench ETR2. For example, a portion of the elastic member 130 may be provided or arranged in the first elastic-member trench ETR1, and a portion of the elastic member 130 may be provided or arranged in the second elastic-member trench ETR2. In some example embodiments, the lower surface (or end) of the elastic member 130 may be provided or arranged on the lower surface of the first elastic-member trench ETR1, and the upper surface (or end) of the elastic member 130 may be provided or arranged on the lower surface of the second elastic-member trench ETR2.

The socket pins 140 may be provided within the base plate 110 and the floating plate 120. In some example embodiments, the socket pins 140 may be provided in the first through-holes TH1 of the base plate 110 and the second through-holes TH2 of the floating plate 120. In some example embodiments, the first through-holes TH1 may vertically overlap (or align) with the second through-holes TH2, respectively, and the socket pins 140 may be inserted into the first through-holes TH1 and the second through-holes TH2 vertically overlapping each other.

Referring to FIGS. 2 and 6, the upper ends of the socket pins 140 may contact corresponding external terminals B (e.g., balls) of a semiconductor package PA, and the lower ends of the socket pins 140 may contact the test board 200. Accordingly, the socket pins 140 may electrically connect the external terminals B of the semiconductor package PA and the test board 200. Each of the socket pins 140 may include a pin body 141 and a pin head 143 on the pin body 141. The pin bodies 141 may generally correspond to the middle and lower portions of the socket pins 140, and the lower ends of the pin bodies 141 may be electrically connected to terminals of the test board 200. Each of the pin bodies 141 may include a spring in the middle portion thereof, and as the springs of the pin bodies 141 are compressed by pressure applied in a direction from the semiconductor package PA toward the pin bodies 141, the pin heads 143 may be moved in the direction from the semiconductor package PA toward the pin bodies 141. The pin heads 143 may correspond to the upper portions of the socket pins 140, and the upper ends of the pin heads 143 may be electrically connected to the semiconductor package PA. The pin heads 143 may contact the external terminals B of the semiconductor package PA. Each of the pin heads 143 may further include an inwardly recessed portion. The pin heads 143, each of which includes the recessed portion, may increase the contact areas with the external terminals B of the semiconductor package PA.

In some example embodiments, the pin bodies 141 may be provided in the first through-holes TH1 or may be provided in the first through-holes TH1 and the second through-holes TH2, and the pin heads 143 may be provided in the second through-holes TH2. In some example embodiments, the levels of the upper ends of the socket pins 140 may be higher than the level of the upper surface of the thin portion 121. In some example embodiments, the level of the upper surface of the thin portion 121 may be lower than the levels of the upper ends of the pin heads 143. In some example embodiments, the levels of the upper ends of the pin bodies 141 may be lower than the level of the upper surface of the thin portion 121. In some example embodiments, the level of the upper surface of the thin portion 121 may be higher than the levels of the upper ends of the pin bodies 141. Accordingly, the level of the upper surface of the thin portion 121 may be located between the levels of the upper ends of the pin bodies 141 and the levels of the upper ends of the pin heads 143.

The cover 150 may be configured to surround the base plate 110 and the floating plate 120 when viewed in a plan view. In some example embodiments, the cover 150 may be provided or arranged along the periphery of the base plate 110 and the floating plate 120 while contacting portions of the base plate 110 and the floating plate 120. In some example embodiments, the upper surface of the cover 150 may be coplanar with a portion of the upper surface of the floating plate 120. For example, the upper surface of the cover 150 may be coplanar with a portion of the upper surface of the edge portion 125. In some example embodiments, the lower surface of the cover 150 may be coplanar with the lower surface 171 of the base plate 110 and/or the upper surface 201 of the test board 200. The cover 150 may be formed of or include at least one of engineering plastics or may be formed of at least one of metal-based materials, such as aluminum-based materials, but is not limited thereto.

The test board 200 may be a printed circuit board (PCB). The test board 200 may be electrically connected to the socket pins 140 and may be configured to transmit and receive test signals. Portions of the test board 200 or the terminals of the test board 200 may be connected to the lower ends of the socket pins 140. The portions of the test board 200 or the terminals of the test board 200 may be coupled to the lower ends of the pin bodies 141.

Referring to FIG. 1, when viewed in a plan view, the thick portion 123 may be configured to surround the thin portion 121 having a quadrangular shape and may be provided in a quadrangular shape corresponding to the shape of the thin portion 121. In some example embodiments, the thin portion 121, the thick portion 123, and the edge portion 125 are disclosed as having a quadrangular shape, but are not limited thereto. In some example embodiments, the shapes of the thin portion 121 and the thick portion 123 may be changed depending on application and/or design and as illustrated in some example embodiments disclosed below.

Referring to FIGS. 2 and 3, the thin portion 121 may be disposed in the central portion of the floating plate 120, and the thick portion 123 may be disposed in the outer portion of the floating plate 120. In some example embodiments, the central portion of the floating plate 120 may be a portion of the floating plate 120 that includes the trench TR and has a relatively smaller thickness, and the outer portion of the floating plate 120 may be a portion of the floating plate 120 that does not include the trench TR and therefore has a relatively larger thickness.

Referring to FIG. 4, when viewed in a plan view, a thin portion 121a may be configured to surround a thick portion 123a having a quadrangular shape and may be provided in a quadrangular shape corresponding to the shape of the thick portion 123a.

Referring to FIG. 5, the thin portion 121a may be disposed in the outer portion of a floating plate 120a, and the thick portion 123a may be disposed in the central portion of the floating plate 120a. In some example embodiments, the outer portion of the floating plate 120a may be a portion of the floating plate 120a that includes a trench TR and therefore has a relatively smaller thickness, and the central portion of the floating plate 120a may be a portion of the floating plate 120a that does not include the trench TR and therefore has a relatively larger thickness.

Referring to FIGS. 3 and 5, the positions of the thin portions 121 and 121a and the thick portions 123 and 123a may be reversed. As illustrated in FIG. 5, the thick portion 123a may be provided at the location where the thin portion 121 is located as illustrated in FIG. 3, and the thin portion 121a may be provided at the location where the thick portion 123 is located as illustrated in FIG. 3.

Referring to FIGS. 6 to 8, the test apparatus 10 may include the test board 200, the test socket 100 provided on the test board 200, and a package driver 300 configured to mount the semiconductor package PA on the test socket 100.

The package driver 300 may fix (or attach or secure) the semiconductor package PA to one surface of the package driver 300. In some example embodiments, the package driver 300 may include, but is not limited to, a device capable of physically fixing or attaching to the semiconductor package PA, such as a gripper, a suction device, or a vacuum chuck. In some example embodiments, the package driver 300 may move the semiconductor package PA by moving while the semiconductor package PA is fixed thereto. In some example embodiments, the package driver 300 may release the semiconductor package PA and may provide or arrange the semiconductor package PA on the test socket 100. In addition, the package driver 300 may mount the semiconductor package PA on the test socket 100 by pressing the semiconductor package PA provided on the test socket 100. In some example embodiments, the package driver 300 may include a body part 310, a fixing part 320, a pressing part 330, and a moving part. The moving part may be configured to change the position of the package driver 300.

The body part 310 may include frames in which the fixing part 320 and the pressing part 330 are disposed and may be provided with various components belonging to the package driver 300.

The fixing part 320 may be or include a physical fixing device or mechanism, such as a gripper, a suction device, or a vacuum chuck, and may fix the semiconductor package PA to the package driver 300. As described above, the fixing part 320 is not limited to any particular device or mechanism, and therefore any device or mechanism capable of fixing the semiconductor package PA to the package driver 300 may be used as the fixing part 320.

The pressing part 330 may include a device or mechanism for applying pressure and may press (e.g., vertically press) the semiconductor package PA provided on the test socket 100. The pressing part 330 may be configured to press the entire semiconductor package PA or may be configured to press a portion of the semiconductor package PA. By applying appropriate pressure to the semiconductor package PA on the test socket 100 through the pressing part 330, the package driver 300 may operate such that the external terminals B of the semiconductor package PA are reliably brought into contact with the socket pins 140 of the test socket 100.

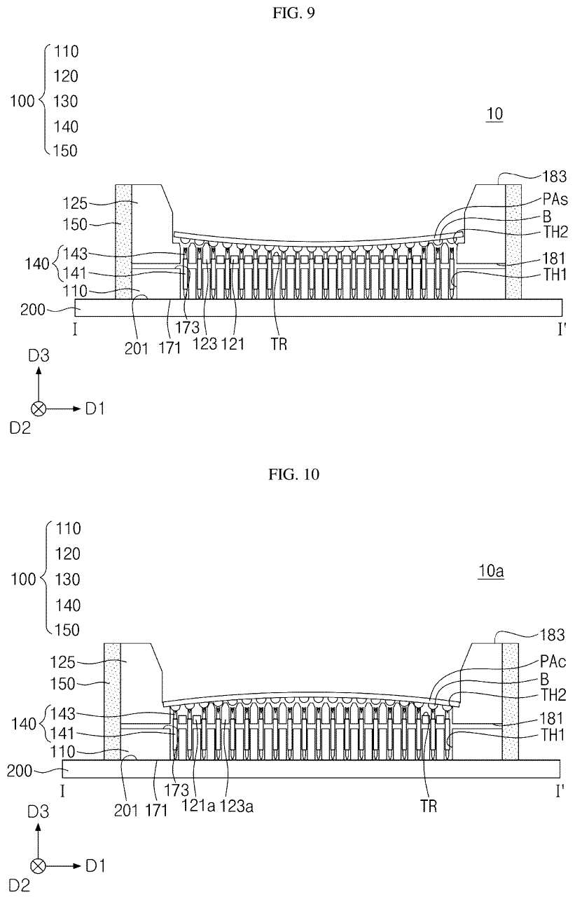

FIGS. 9 and 10 are cross-sectional views illustrating the test apparatuses according to the some example embodiments of the present disclosure.

Referring to FIGS. 9 and 10, the arrangement of the thin portion 121 or 121a and the thick portion 123 or 123a of the floating plate 120 or 120a suitable for use may be determined depending on bending directions of semiconductor packages PAs and PAc. For example, when a shrinkage difference occurs due to low temperature as illustrated in FIG. 9, the semiconductor package PAs may have a shape that is concave downward (or a smiley shape). In some example embodiments, the floating plate 120 may have a relatively thinner central portion and a relatively thicker outer portion. For example, when a tensile difference occurs due to high temperature as illustrated in FIG. 10, the semiconductor package PAc may have a shape that is concave upward (or, a crying shape). In some example embodiments, the floating plate 120a may have a relatively thicker central portion and a relatively thinner outer portion.

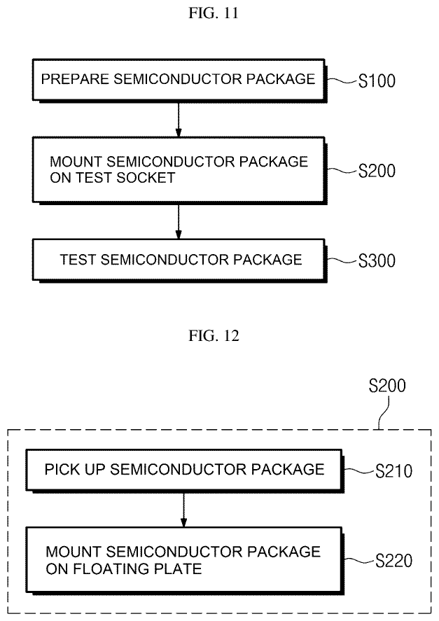

FIGS. 11 and 12 are flowcharts illustrating a test apparatus operating method according to some example embodiments of the present disclosure.

Referring to FIG. 11, the test apparatus operating method according to some example embodiments of the present disclosure may include preparing a semiconductor package (S100), mounting the semiconductor package on a test socket (S200), and testing the semiconductor package (S300). Referring to FIG. 12, the mounting of the semiconductor package on the test socket (S200) may include picking up the semiconductor package (S210) and mounting the semiconductor package on a floating plate (S220). The test apparatus operating method is discussed below.

Referring to FIGS. 6 and 11, the semiconductor package PA may be prepared or provided, and the semiconductor package PA may be fixed or attached or secured to the package driver 300.

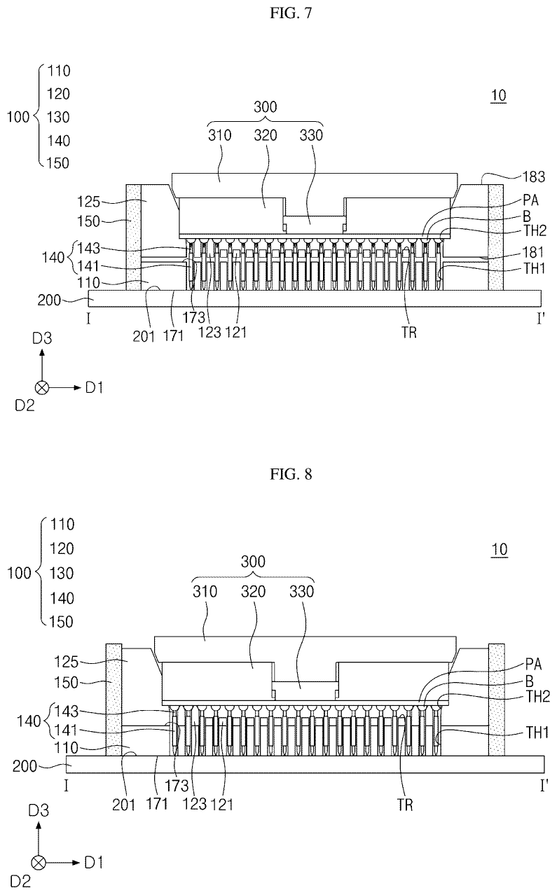

Referring to FIGS. 7, 11, and 12, the semiconductor package PA fixed to the package driver 300 may be moved by the movement of the package driver 300 and may be provided on or placed on the floating plate 120. In a test apparatus operating method, the semiconductor package PA may be picked up to the position (or location) of the floating plate 120 by the package driver 300. The package driver 300 may select the arrangement of the thin portion 121 and the thick portion 123 of the floating plate 120 depending on the bending direction (or shape) of the semiconductor package PA. The package driver 300 may move the semiconductor package PA to the floating plate 120 having the selected (or desired) arrangement of the thin portion 121 and the thick portion 123. The floating plate 120 according to some example embodiments may include the edge portion 125 that surrounds the thin portion 121 and the thick portion 123 when viewed in a plan view, and the upper surface of the edge portion 125 may be higher than the upper end of the thick portion 123. The edge portion 125 may guide the edge of the semiconductor package PA while mounting the semiconductor package PA on the floating plate 120. The semiconductor package PA guided by the edge portion 125 may be brought into contact with a portion of the floating plate 120 while the semiconductor package PA is fixed to or held by the package driver 300.

Referring to FIGS. 3, 8, 11, and 12, the semiconductor package PA may release the package driver 300, and the semiconductor package PA may be brought into contact with a portion of the floating plate 120. Thereafter, the package driver 300 may vertically press the semiconductor package PA to lower the position level of the floating plate 120. The pressure applied by the package driver 300 may be transmitted to the floating plate 120 through the semiconductor package PA, and the pressure transmitted to the floating plate 120 may be transmitted to the elastic member 130. As the elastic member 130 is vertically compressed by the transmitted pressure, the position level of the floating plate 120 may be lowered. Although the base plate 110 and the floating plate 120 are spaced apart from each other by the elastic member 130 before the application of the pressure, the distance between the base plate 110 and the floating plate 120 may be decreased as the elastic member 130 is compressed by the pressure of the package driver 300, and a portion of the base plate 110 and a portion of the floating plate 120 may be brought into contact with each other when the base plate 110 and the floating plate 120 contact each other (e.g., when the distance between them reaches 0). When the position level of the elastic member 130 and/or the socket pins 140 according to some example embodiments is decreased to a set value or less, the position level of the elastic member 130 and/or the socket pins 140 may be fixed. Accordingly, the semiconductor package PA may be mounted on the floating plate 120.

According to some example embodiments, when the semiconductor package PA is mounted on the floating plate 120, the semiconductor package PA may contact the thick portion 123 of the floating plate 120 but may not be brought into contact with the thin portion 121 of the floating plate 120. Since the thin portion 121 is thinner than the thick portion 123 and includes the upper end having a lower level than the upper end of the thick portion as described above, the semiconductor package PA may not be brought into contact with the thin portion 121.

Referring to FIGS. 8 and 11, a test process may be performed on the semiconductor package PA mounted on the floating plate 120. In some example embodiments, the test board 200 may apply test signals to the socket pins 140, and the socket pins 140 may transfer the provided test signals to the external terminals B of the semiconductor package PA. The test signals input through the external terminals B of the semiconductor package PA may be processed into signals by the circuit or logic inside the semiconductor package PA and the processed signals may then be provided to the external terminals B of the semiconductor package PA. The input test signals may be modified after being processed by the circuit or logic inside the semiconductor package PA or may be provided to the external terminals B of the semiconductor package PA without change. The signals provided from the external terminals B of the semiconductor package PA may be transferred to the test board 200 via the socket pins 140, and whether the semiconductor package PA normally operates or not may be determined based on signals transferred from the test board 200 or other devices connected to the test board 200.

After the test is performed, the semiconductor package PA mounted on the floating plate 120 may be detached (or, unloaded).

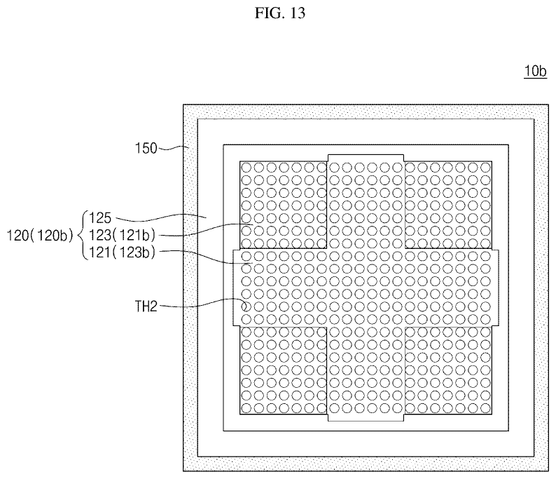

FIGS. 13 to 16 are plan views of test apparatuses 10b-10e according to some example embodiments of the present disclosure. The test apparatuses of FIGS. 13-16 may be the same as or similar in some respects to the test apparatuses of FIGS. 1, 4, and 13 to 16, and therefore may be best understood with reference thereto where like numerals indicate like elements not described again in detail.

Referring to FIGS. 1, 4, and 13 to 16, the trench TR in the floating plate 120 of the test socket 100 of the test apparatuses 10, 10a, 10b, 10c, 10d, and 10e may have different shapes. As described above, the trenches TR of FIGS. 1 and 4 may be formed in a quadrangular shape when viewed in a plan view, and, in the trench TR of FIG. 4, the positions of the thin portion 121 of FIG. 1 and the thick portion 123 of FIG. 1 may be reversed in FIG. 4 such that the thick portion 123a of FIG. 4 is in place of the thin portion 121 of FIG. 1, and the thin portion 121a of FIG. 4 is in place of the thick portion 123 of FIG. 1.

Referring to FIG. 13, the trench TR in the floating plate 120 may have a plus shape (or, a cross shape) generally defined by two rectangles intersecting each other in a vertical direction when viewed in a plan view. In some example embodiments, since the portion in the trench TR corresponds to the thin portion 121, the thickness of the thin portion 121 of the floating plate 120 in the plus shape may be smaller than the thickness of the thick portion 123 of the floating plate 120 outside the plus shape. In some example embodiments, when the position of the trench TR is interchanged (or reversed), the thick portion 123 may be in the position of a thin portion 121b, and the thin portion 121 may be in the position of a thick portion 123b.

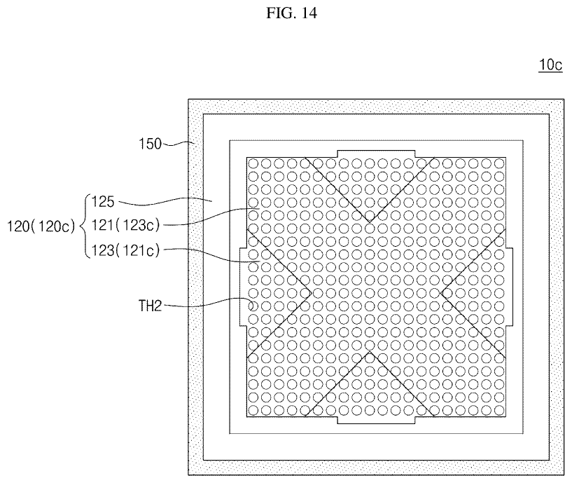

Referring to FIG. 14, the trench TR in the floating plate 120 may have an X-shape generally defined by two rectangles that diagonally intersect each other when viewed in a plan view. In some example embodiments, since the portion in the trench TR corresponds to the thin portion 121, the thickness of the thin portion 121 of the floating plate 120 in the X-shape may be smaller than the thickness of the thick portion 123 of the floating plate 120 outside the X-shape. In some example embodiments, when the position of the trench TR is reversed or interchanged, the thick portion 123 may be in the position of a thin portion 121c, and the thin portion 121 may be in the position of a thick portion 123c.

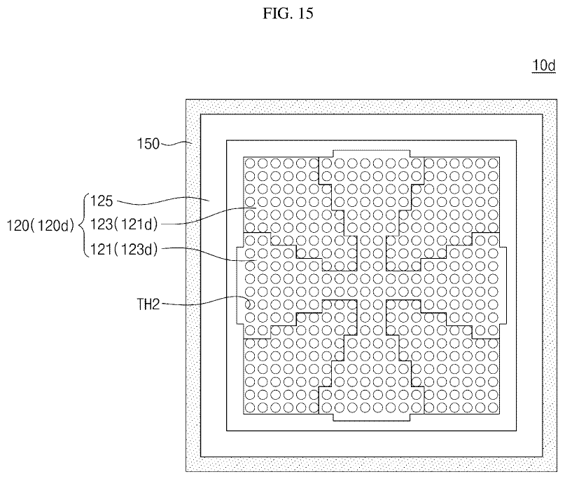

Referring to FIG. 15, the trench TR in the floating plate 120 may have a windmill shape (or a pinwheel shape, a combined shape of four blades, or a shape of fan blades) generally defined by four blade shapes that intersect at the center when viewed in a plan view. In some example embodiments, since the portion in the trench TR corresponds to the thin portion 121, the thickness of the thin portion 121 of the floating plate 120 in the windmill shape may be smaller than the thickness of the thick portion 123 of the floating plate 120 outside the windmill shape. In some example embodiments, when the position of the trench TR is reversed or interchanged, the thick portion 123 may be in the position of a thin portion 121d, and the thin portion 121 may be in the position of a thick portion 123d.

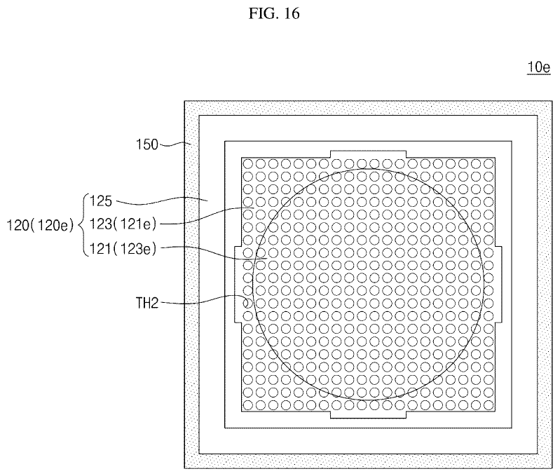

Referring to FIG. 16, the trench TR in the floating plate 120 may have a circular shape when viewed in a plan view. In some example embodiments, since the portion in the trench TR corresponds to the thin portion 121, the thickness of the thin portion 121 of the floating plate 120 in the circular shape may be smaller than the thickness of the thick portion 123 of the floating plate 120 outside the circular shape. In some example embodiments, when the position of the trench TR is reversed or interchanged, the thick portion 123 may be in the position of a thin portion 121e, and the thin portion 121 may be in the position of a thick portion 123e.

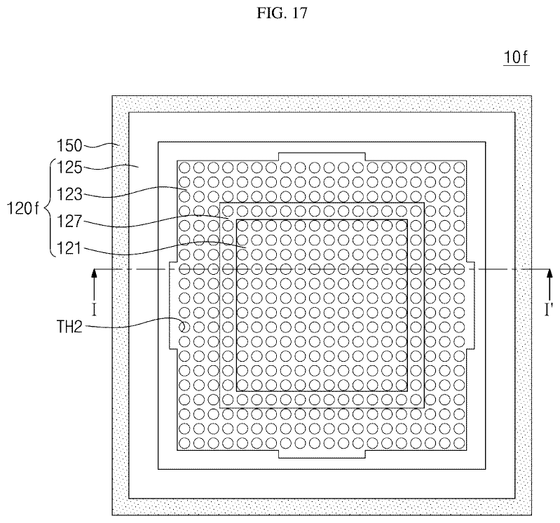

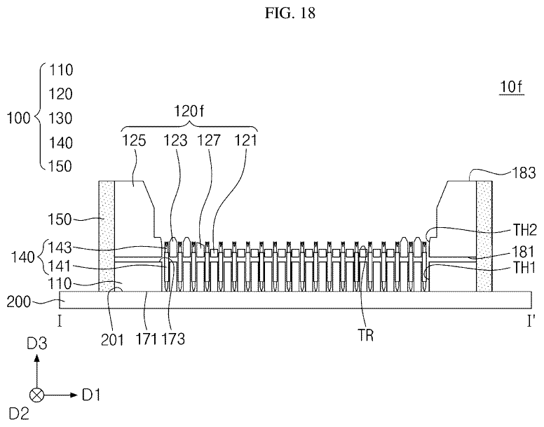

FIG. 17 is a plan view illustrating a test apparatus 10f according to some example embodiments of the present disclosure. FIG. 18 is a cross-sectional view taken along line I-I′ of FIG. 17. The test apparatus 10f may be the same as or similar in some respects to the test apparatus 10 of FIG. 1, and therefore may be best understood with reference thereto where like numerals indicate like elements not described again in detail. In FIGS. 17 and 18, a floating plate 120f further includes an inclined portion 127.

Referring to FIGS. 17 and 18, when the floating plate 120f is recessed to form a trench TR, the trench TR may have an inner surface inclined from the upper surface of the floating plate 120f toward the lower surface of the floating plate 120f. The inclined portion 127 may be a body of the floating plate 120f under the inclined inner surface of the trench TR. The inclined portion 127 may be a portion of the floating plate 120f that is thinner than a thick portion 123 and thicker than a thin portion 121. In some example embodiments, the inclined portion 127 may be a body of the floating plate 120f between the thin portion 121 and the thick portion 123.

The inclined portion 127 may be provided between the thin portion 121 and the thick portion 123 when viewed in a plan view. In some example embodiments, the inclined portion 127 may space the thin portion 121 and the thick portion 123 apart from each other while contacting both a portion of the thin portion 121 and a portion of the thick portion 123.

In some example embodiments, the inclined portion 127 may have or define a plurality of second through-holes TH2. In some example embodiments, the second through-holes TH2 may penetrate the upper and lower surfaces of the inclined portion 127 and the body of the inclined portion 127 between the upper and lower surfaces of the inclined portion 127.

In some example embodiments, the lower surface of the inclined portion 127 may be coplanar with the lower surfaces of the thin portion 121 and the thick portion 123. Since the inclined portion 127 is thicker than the thin portion 121 and thinner than the thick portion 123 as described above, the upper end of the inclined portion 127 may be higher than the upper end of the thin portion 121 and lower than the upper end of the thick portion 123.

The inclined portion 127 may be formed of or include a material different from that of at least one of the thin portion 121, the thick portion 123, or the edge portion 125, and one or more of the thin portion 121, the thick portion 123, and the edge portion 125 may be formed of or include the same material or similar materials. Alternatively, the thin portion 121, the thick portion 123, and the edge portion 125 may be formed of or include the same material. When the thin portion 121, the thick portion 123, and the edge portion 125 are formed of or include the same material, the thin portion 121, the thick portion 123, and the edge portion 125 may be integrally formed with one another, and may, for example, form a single, unitary structure.

As described above, according to some example embodiments of the present disclosure, the contact area between the semiconductor package and the test socket may be reduced in the test process. Accordingly, electrostatic charges that may be accumulated as the test process is repeatedly performed may be reduced. In addition, the test process may be performed with relative ease on the slightly bent or curved semiconductor packages. Accordingly, damage to the semiconductor package due to bending of the semiconductor package during the test process may be reduced, and thus the yield of the semiconductor package may be increased.

As described above, according to some example embodiments of the present disclosure, the contact area between the semiconductor package and the test socket may be reduced in the test process. Accordingly, the amount of electrostatic charge accumulated as the test process is repeatedly performed may be reduced.

According to some example embodiments, a test apparatus operating method includes preparing a semiconductor package and mounting the semiconductor package on a test socket. The test socket includes a base plate defining first through-holes, a floating plate over the base plate and defining second through-holes vertically overlapping the respective first through-holes and including a thin portion and a thick portion having a thickness greater than a thickness of the thin portion, and socket pins in the first through-holes and the second through-holes, the first through-holes and the second through-holes vertically overlapping with each other. The test apparatus operating method further includes testing the semiconductor package by applying test signals to a test board provided under the test socket.

When the semiconductor package is mounted on the floating plate, the semiconductor package may be brought into contact with the thick portion of the floating plate and may not be brought into contact with the thin portion of the floating plate.

The mounting of the semiconductor package on the test socket may include moving the semiconductor package by a package driver and mounting the moved semiconductor package on the floating plate.

The test socket may further include at least one elastic member provided between the base plate and the floating plate, and the elastic member may be configured to space the base plate and the floating plate apart from each other.

The mounting of the moved semiconductor package on the floating plate may include pressing the semiconductor package and fixing the semiconductor package such that a position of the floating plate is lowered.

The moving of the semiconductor package by the package driver may include selecting, by the package driver, the test socket depending on a bending direction of the semiconductor package and moving, by the package driver, the semiconductor package onto the selected test socket.

The floating plate may further include an edge portion that surrounds the thin portion and the thick portion when viewed in a plan view, and a level of an upper surface of the edge portion may be higher than a level of an upper end of the thick portion.

The edge portion may be configured to guide an edge of the semiconductor package when the semiconductor package is mounted on the test socket.

The test apparatus operating method may further include unloading the semiconductor package after the testing of the semiconductor package.

The testing of the semiconductor package may include determining whether the semiconductor package operates normally based on the test signals.

Example embodiments are not necessarily mutually exclusive. For example, some example embodiments may include one or more features described with reference to one or more figures, and may also include one or more other features described with reference to one or more other figures.

While several embodiments have been provided in the present disclosure, it should be understood that the disclosed systems and methods might be embodied in many other specific forms without departing from the spirit or scope of the present disclosure. The present examples are to be considered as illustrative and not restrictive, and the intention is not to be limited to the details given herein. For example, the various elements or components may be combined or integrated in another system or certain features may be omitted, or not implemented.

What is claimed is:

1. A test socket comprising:
a base plate defining first through-holes;
a floating plate over the base plate, the floating plate defining second through-holes configured to vertically overlap the respective first through-holes, wherein the floating plate includes a thin portion and a thick portion having a thickness greater than a thickness of the thin portion; and
socket pins in the first through-holes and the second through-holes, the first through-holes and the second through-holes vertically overlapping with each other.

2. The test socket of claim 1, wherein a lower surface of the thin portion is coplanar with a lower surface of the thick portion, and
wherein an upper surface of the thin portion is lower than an upper surface of the thick portion.

3. The test socket of claim 1, wherein a planar area of the thin portion ranges from 50% to 80% of a sum of planar areas of the thin portion and the thick portion.

4. The test socket of claim 1, wherein a difference between the thickness of the thin portion and the thickness of the thick portion ranges from 0.05 mm to 5 mm.

5. The test socket of claim 1, wherein an upper surface of the thin portion is lower than upper ends of the socket pins.

6. The test socket of claim 1, wherein each socket pin includes a pin body and a pin head on the pin body, and
wherein an upper surface of the thin portion is higher than an upper end of the pin body.

7. The test socket of claim 1, wherein the floating plate further includes an edge portion configured to surround the thin portion and the thick portion when viewed in a plan view, and
wherein an upper surface of the edge portion is higher than an upper surface of the thick portion.

8. The test socket of claim 7, wherein the thin portion, the thick portion, and the edge portion are integral with one another.

9. The test socket of claim 8, further comprising:
an elastic member between the base plate and the floating plate.

10. The test socket of claim 1, further comprising:
a cover configured to surround the base plate and the floating plate when viewed in a plan view.

11. A test socket comprising:
a base plate defining first through-holes;
a floating plate over the base plate, the floating plate having a trench recessed from a portion of an upper surface of the floating plate, wherein the floating plate includes a thick portion on a first side of the trench and a thin portion in the trench, the floating plate defines second through-holes configured to penetrate the thin portion and the thick portion, and the second through-holes vertically overlap the respective first through-holes; and
socket pins in the first through-holes and the second through-holes, the first through-holes and the second through-holes vertically overlapping with each other.

12. The test socket of claim 11, wherein an inner surface of the trench is perpendicular to a lower surface of the floating plate.

13. The test socket of claim 11, wherein an inner surface of the trench is inclined with respect to a lower surface of the floating plate.

14. The test socket of claim 11, wherein a planar area of the thin portion ranges from 50% to 80% of a sum of planar areas of the thin portion and the thick portion.

15. The test socket of claim 11, wherein a difference between a thickness of the thin portion and a thickness of the thick portion ranges from 0.05 mm to 5 mm.

16. The test socket of claim 11, wherein an upper surface of the thin portion is lower than upper surfaces of the socket pins.

17. A test apparatus comprising:
a test board;
a base plate on the test board, the base plate defining first through-holes;
a floating plate over the base plate, the floating plate defining second through-holes configured to vertically overlap the respective first through-holes, wherein the floating plate includes a thin portion and a thick portion having a thickness greater than a thickness of the thin portion; and
socket pins in the first through-holes and the second through-holes, the first through-holes and the second through-holes vertically overlapping with each other,
wherein the test board is configured to be electrically connected to the socket pins and configured to transmit and receive test signals.

18. The test apparatus of claim 17, wherein a lower surface of the thin portion is coplanar with a lower surface of the thick portion, and
wherein an upper surface of the thin portion is lower than an upper surface of the thick portion.

19. The test apparatus of claim 18, wherein a difference between the thickness of the thin portion and the thickness of the thick portion ranges from 0.05 mm to 5 mm.

20. The test apparatus of claim 17, further comprising:
a package driver configured to move a semiconductor package onto the floating plate,
wherein the package driver is configured to press the semiconductor package.
